(19) United States
(12) Patent Application Publication
(10) Pub. No.: US 2006/0195748 A1
(43) Pub. Date: Aug. 31, 2006

(54) Electronic product testing procedure supervising method and system

(75) Inventors: Jia-Chuan Chen, Taipei (TW); Ling Wang, Taipei (TW)

Correspondence Address: EDWARDS & ANGELL, LLP, P.O. BOX 55874, BOSTON, MA, 02205, US

(73) Assignee: Inventec Corporation, Taipei (TW)

(21) Appl. No.: 11/067,544

(22) Filed: Feb. 25, 2005

(51) Int. Cl. G01R 31/28; G06F 11/00

(52) U.S. Cl. 714/742

(57) ABSTRACT

An electronic product testing procedure supervising method and system is proposed, which is designed for use in conjunction with a testing platform and a supervising platform in a factory, and which is characterized by the capability of recording a set of data related to the performance of each step in every testing procedure as well as the product serial number of each electronic product being tested on each testing platform and operated by test engineers, such that QC supervising personnel can check whether test engineers have dutifully followed and carried out all required test procedures in the testing of electronic products, and whether all manufactured electronic products have undergone the testing procedure without being inadvertently or purposefully left untested. This feature allows the quality control of electronic products in a factory to be more reliable and assured.

### BACKGROUND OF THE INVENTION

1. Field of the Invention

This invention relates to quality control (QC) technology for electronic products, and more particularly, to an electronic product testing procedure supervising method and system which is designed for use in a production line for providing a testing procedure supervising function that is capable of automatically supervising the performance of a human-operated testing procedure that is human-operated by test engineers on a batch of electronic products, such as desktop computers, notebook computers, tablet computers, pocket computers, network server, and so on, for the purpose of assuring that every electronic product in the production line has properly undergone the testing procedure.

2. Description of Related Art

In the manufacture of electronic products, such as desktop computers, notebook computers, tablet computers, pocket computers, network server, and so on, it is a standard practice to perform a testing procedure on the manufactured electronic products before shipping to the market or customers, so as to assure that every electronic product shipped to the market or customers can operate normally. If any defect is found in an electronic product during the testing procedure, the defective electronic product must be reengineered and cannot be shipped out to the market.

In practice, however, since a production line in factory typically manufactures hundreds or thousands units of electronic products, some of the electronic products may be negligently untested and shipped out to the market. Moreover, since the testing procedure is typically tedious, laborious, and time-consuming, some undutiful test engineers may purposefully let some units pass their testing stations without being tested, thus causing several untested units of electronic products to be shipped to the market, which would cause harm to the company's reputation and credit.

### SUMMARY OF THE INVENTION

It is therefore an objective of this invention to provide a computer platform system image automatic loading method and system which allows QC supervising personnel in a factory to supervise whether test engineers have dutifully followed and carried out all required test procedures in the testing of electronic products.

It is another objective of this invention to provide a computer platform system image automatic loading method and system which allows the quality control of electronic products in a factory to be more reliable and assured.

The computer platform system image automatic loading method and system according to the invention is designed for use in a production line for providing a testing procedure supervising function that is capable of automatically supervising the performance of a human-operated testing procedure that is human-operated by test engineers on a batch of electronic products, such as desktop computers, notebook computers, tablet computers, pocket computers, network server, and so on, for the purpose of assuring that every electronic product in the production line has properly undergone the testing procedure.

The computer platform system image automatic loading method and system according to the invention is characterized by the capability of recording a set of data related to the performance of each step in every testing procedure as well as the product serial number of the electronic product being tested on the testing platform and operated by the test engineer, such that the QC supervising personnel can check whether test engineers have dutifully followed and carried out all required test procedures in the testing of electronic products, and whether all manufactured electronic products in the factory have undergone the testing procedure without being inadvertently or purposefully left untested. This feature allows the quality control of electronic products in a factory to be more reliable and assured.

### BRIEF DESCRIPTION OF DRAWINGS

The invention can be more fully understood by reading the following detailed description of the preferred embodiments, with reference made to the accompanying drawings, wherein:

FIG. 1 is a schematic diagram showing the application architecture of the electronic product testing procedure supervising system according to the invention; and

FIG. 2 is a schematic diagram showing the modularized object-oriented component model of the internal architecture of the electronic product testing procedure supervising system according to the invention.

### DETAILED DESCRIPTION OF PREFERRED EMBODIMENTS

The electronic product testing procedure supervising method and system according to the invention is disclosed in full details by way of preferred embodiments in the following with reference to the accompanying drawings.

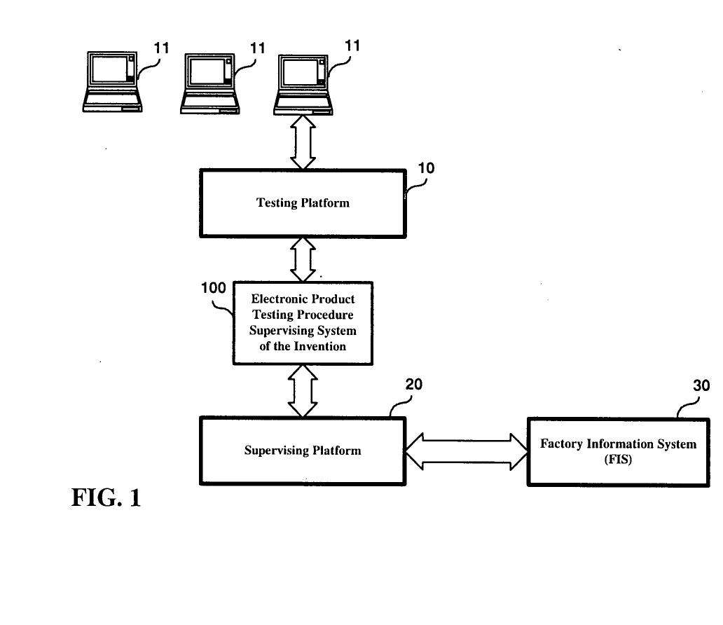

FIG. 1 is a schematic diagram showing the application architecture of the electronic product testing procedure supervising system of the invention 100. As shown, the electronic product testing procedure supervising system of the invention 100 is designed for use in conjunction with a computer-based supervising platform 20 and a computer-based testing platform 10, wherein the testing platform 10 is used to perform a human-operated testing procedure on a batch of electronic products 11, such as desktop computers, notebook computers, tablet computer, pocket computers, network servers, and so on; while the supervising platform 20 is used by QC supervising personnel to supervise whether each human-operated testing procedure performed on the electronic product 11 by the testing platform 10 has been properly conducted in accordance with standard operating specifications.

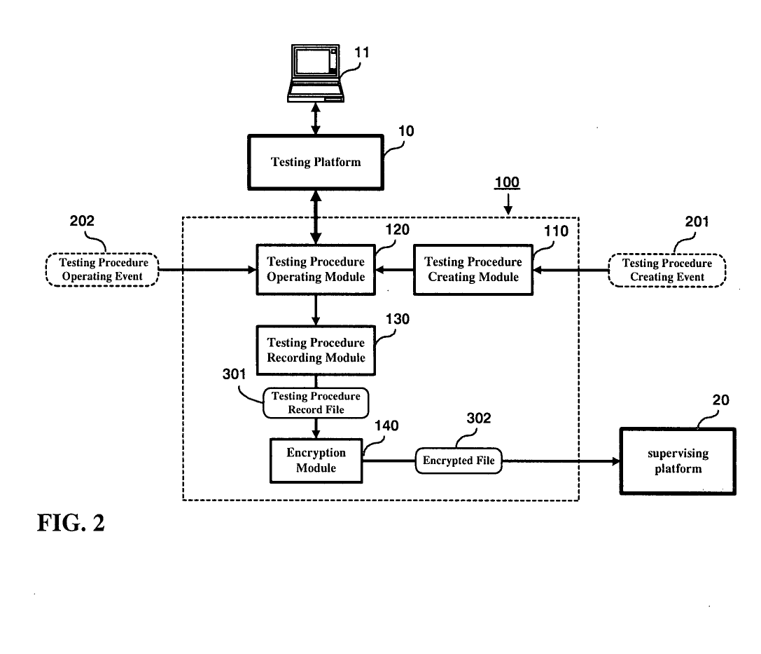

As shown in FIG. 2, the modularized object-oriented component model of the electronic product testing procedure supervising system of the invention 100 comprises: (a) a testing procedure creating module 110; (b) a testing procedure operating module 120; and (c) a testing procedure recording module 130; and can further optionally comprise an encryption module 140.

The testing procedure creating module 110 is used to provide a human-operated testing procedure creating function for use by a human worker, such as a QC system design engineer, to create a standard computer-executable testing interface and procedure which is to be executed by the testing platform 10 to perform a human-operated testing procedure on the electronic product 11. Since different kinds of electronic products, such as notebook computers and tablet computers, have different system configurations, the required testing procedures for these two different kinds of electronic products may be different, and therefore require different testing interface and procedures.

The testing procedure operating module 120 is capable of executing the computer code of each set of standard testing interface and procedure created by the above-mentioned testing procedure creating module 110 and responding to a human-initiated testing procedure operating event 202 (which is initiated by a human worker such as a test engineer) by conducting a testing procedure on the electronic product 11. During this testing procedure, the test engineer is required to operate via the standard testing interface and follow the standard operating procedure specified by the testing procedure creating module 110 to manually operate the testing platform 10 to perform each required step in the testing procedure.

The testing procedure recording module 130 is capable of recording a set of data related to the performance of the testing procedure conducted by the testing platform 10 and operated by the test engineer in the testing of the electronic product 11. The recorded data include, for example, identification of the test engineer (such as the login username of the test engineer), start time of the testing procedure, performance of each manually-initiated procedural step in the testing procedure, completion time of the testing procedure, serial number of the electronic product 11 being tested, and so on. The recorded data are collected into a testing procedure record file 301 in electronic form.

The encryption module 140 is capable of performing an encryption procedure on the testing procedure record file 301 generated by the above-mentioned testing procedure recording module 130. The encryption procedure converts the testing procedure record file 301 into an encrypted file 302 for uploading in encrypted form to the supervising platform 20 where the QC supervising personnel can view the performance of each testing procedure on the testing platform 10 by decrypting the encrypted file 302 and display the decrypted contents (i.e., the original contents of the testing procedure record file 301) on the supervising platform 20. Through browsing the contents of the testing procedure record file 301, it allows the QC supervising personnel to check whether the testing procedure on the electronic product 11 has been dutifully followed and carried out by the test engineer at the testing platform 10.

Referring to FIG. 1 together with FIG. 2, in actual operation of the testing on the electronic product 11, the QC system design engineer first needs to utilize the testing procedure creating module 110 to create a standard computer-executable testing interface and procedure for this particular kind of the electronic product 11 under testing. The testing procedure creating module 110 will respond to the human-operated testing procedure creating event 201 by creating a set of computer code for the testing interface and procedure and download the computer code to the testing procedure operating module 120.

During actual testing, the computer code of the standard testing interface and procedure created by the testing procedure creating module 110 is executed by the testing procedure operating module 120, and the test engineer at the testing platform 10 is required to operate on the standard testing interface and follow the standard operating procedure that is displayed on the testing procedure operating module 120 for the purpose of activating the testing platform 10 to perform a testing procedure on the electronic product 11. Each manual operating action by the test engineer causes the occurrence of a human-initiated testing procedure operating event 202, which causes the testing procedure operating module 120 to respond by executing the corresponding step in the testing procedure. During this testing procedure, the testing procedure recording module 130 is also activated to record a set of data related to the performance of each step in the testing procedure conducted on the testing platform 10 and operated by the test engineer. The recorded data include, for example, identification of the test engineer, start time of the testing procedure, performance of each manually-initiated procedural step in the testing procedure, completion time of the testing procedure, serial number of the electronic product 11 being tested, and so on. The recorded data are collected into a testing procedure record file 301 in electronic form; and then after the testing procedure is completed, the encryption module 140 is activated to perform an encryption procedure on the testing procedure record file 301 to convert it into an encrypted file 302 for uploading in encrypted form to the supervising platform 20.

The QC supervising personnel at the supervising platform 20 can then view the performance of each testing procedure on the testing platform 10 by decrypting the encrypted file 302 and display the decrypted contents (i.e., the original contents of the testing procedure record file 301) on the supervising platform 20. Through browsing the contents of the testing procedure record file 301, it allows the QC supervising personnel to check whether the testing procedure on the electronic product 11 has been dutifully followed and carried out by the test engineer at the testing platform 10. Moreover, by collecting the product serial numbers from all the testing procedure record files 301 from all testing platforms 10 in the factory, it can be checked that whether all the units in a batch of electronic products have undergone the testing procedure without being inadvertently or purposefully left untested by the test engineer.

In addition, the supervising platform 20 can further upload all the testing procedure record files 301 received from all testing platforms 10 in the factory to an FIS (Factory Information System) 30 so as to allow other working staff members in the company to share and browse these data via a network system, such as Internet or intranet.

In conclusion, the invention provides a computer platform system image automatic loading method and system for use with a testing platform and a supervising platform, and which is characterized by the capability of recording a set of data related to the performance of each step in every testing procedure as well as the product serial number of the electronic product being tested on the testing platform and operated by the test engineer, such that the QC supervising personnel can check whether test engineers have dutifully followed and carried out all required test procedures in the testing of electronic products, and whether all manufactured electronic products in the factory have undergone the testing procedure without being inadvertently or purposefully left untested. This feature allows the quality control of electronic products in a factory to be more reliable and assured. The invention is therefore more advantageous to use than the prior art.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. An electronic product testing procedure supervising method for use on a testing platform and a supervising platform for the supervising platform to supervise the performance of a human-operated testing procedure conducted by the testing platform on an electronic product;
the electronic product testing procedure supervising method comprising:
creating a standard computer-executable testing interface and procedure for the electronic product to be tested;
executing the standard testing interface and procedure for the testing platform to conduct a human-operated testing procedure on the electronic product; and
recording a set of data related to the performance of the human-operated testing procedure conducted on the testing platform for building a testing procedure record file therefrom in electronic form for uploading to the supervising platform

2. The electronic product testing procedure supervising method of claim 1, wherein the electronic product is a desktop computer.

3. The electronic product testing procedure supervising method of claim 1, wherein the electronic product is a notebook computer.

4. The electronic product testing procedure supervising method of claim 1, wherein the electronic product is a tablet computer.

5. The electronic product testing procedure supervising method of claim 1, wherein the electronic product is a pocket computer.

6. The electronic product testing procedure supervising method of claim 1, wherein the electronic product is a network server.

7. The electronic product testing procedure supervising method of claim 1, further comprising:
performing an encryption procedure on the testing procedure record file for uploading the testing procedure record file in encrypted form to the supervising platform.

8. An electronic product testing procedure supervising system for use with a testing platform and a supervising platform for the supervising platform to supervise the performance of a human-operated testing procedure conducted by the testing platform on an electronic product;
the electronic product testing procedure supervising system comprising:
a testing procedure creating module, which is capable of providing a human operated testing procedure creating function for creating a standard computer-executable testing interface and procedure for the electronic product to be tested;
a testing procedure operating module, which is capable of executing the standard testing interface and procedure created by the testing procedure creating module for the testing platform to conduct a human-operated testing procedure on the electronic product; and
a testing procedure recording module, which is capable of recording a set of data related to the performance of the human-operated testing procedure conducted on the testing platform for building a testing procedure record file therefrom in electronic form for uploading to the supervising platform.

9. The electronic product testing procedure supervising system of claim 8, wherein the electronic product is a desktop computer.

10. The electronic product testing procedure supervising system of claim 8, wherein the electronic product is a notebook computer.

11. The electronic product testing procedure supervising system of claim 8, wherein the electronic product is a tablet computer.

12. The electronic product testing procedure supervising system of claim 8, wherein the electronic product is a pocket computer.

13. The electronic product testing procedure supervising system of claim 8, wherein the electronic product is a network server.

14. The electronic product testing procedure supervising system of claim 8, further comprising:
an encryption module, which is capable of performing an encryption procedure on the testing procedure record file for uploading the testing procedure record file in encrypted form to the supervising platform.
